(19) United States
(12) Patent Application Publication
(10) Pub. No.: US 2016/0307993 A1
(43) Pub. Date: Oct. 20, 2016

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Hidenao KURIBAYASHI, Matsumoto-city (JP); Shoji KITAMURA, Matsumoto-city (JP); Yuichi ONOZAWA, Matsumoto-city (JP)

(73) Assignee: FUJI ELECTRIC CO., LTD., Kawasaki-shi (JP)

(21) Appl. No.: 15/197,821

(22) Filed: Jun. 30, 2016

Related U.S. Application Data
(63) Continuation of application No. PCT/JP2015/070335, filed on Jul. 15, 2015.

(30) Foreign Application Priority Data
Jul. 17, 2014 (JP) 2014-146929

(51) Int. Cl. H01L 29/06; H01L 27/06; H01L 21/324; H01L 29/78; H01L 21/22; H01L 21/265

(52) U.S. Cl. CPC H01L 29/063; H01L 21/221; H01L 21/265; H01L 21/324; H01L 29/0623; H01L 29/7805; H01L 27/0664

(57) ABSTRACT

A defective layer is formed by ion implanting argon for a p⁺ anode layer from a front surface side of a base substrate. Here, the range of the argon is set to be shallower than the diffusion depth of the p⁺ anode layer such that platinum atoms are localized in an electron entering region near a pn junction of the p⁺ anode layer with an n⁻ drift layer at a platinum diffusion step executed later. The platinum atoms in a platinum paste applied to the back surface of the base substrate are thereafter diffused in the p⁺ anode layer to be localized on a cathode side of the defective layer.

### CROSS REFERENCE TO RELATED APPLICATIONS

This is a continuation application of International Application PCT/JP2015/070335 filed on Jul. 15, 2015 which claims priority from a Japanese Patent Application No. 2014-146929 filed on Jul. 17 2014, the contents of which are incorporated herein by reference.

### BACKGROUND OF THE INVENTION

1. Field of the Invention

The embodiments of the invention relate to a semiconductor device and a method of manufacturing a semiconductor device.

2. Description of the Related Art

Platinum (element symbol: “Pt”) is useful as a lifetime killer to facilitate improved reverse recovery property and reduced leak current, and is often applied to a diode product and the like. A method (manufacturing process steps) of a conventional semiconductor device will be described taking an example of a case where a p-i-n diode is manufactured (conventional manufacturing process 1). FIG. 9 is a flowchart of an overview of a method of manufacturing a conventional semiconductor device. FIG. 9 depicts process steps of introducing platinum atoms 61 to be the lifetime killer, in a manufacturing process of a p-i-n diode 500 of FIGS. 10A and 10B.

FIGS. 10A and 10B are explanatory diagrams of a state in the course of the manufacturing process of the conventional p-i-n diode 500. FIG. 10A is a cross-sectional diagram of the conventional p-i-n diode 500, and FIG. 10B is a distribution diagram of the platinum concentration of a semiconductor base substrate. FIG. 10A depicts the state of vapor deposition or sputtering of the platinum atoms 61, where solid lines depict a cross-sectional view of the state in the course of the manufacturing process and the portions to be disposed at subsequent manufacturing process steps (a front surface electrode 62 to be an anode electrode, and a back surface electrode 63 to be a cathode electrode) are depicted using dotted lines. Further, D represents a depth. In the description hereinafter, each number in parentheses corresponds to the number in parentheses depicted in FIG. 9 and represents the order of the process step.

In FIG. 9, (1) is a mask member formation process (step S81). A mask member having an opening 53 is disposed on a surface (a surface on the opposite side with respect to an n⁺ semiconductor substrate 51 side) of an n⁻ semiconductor layer 52 disposed on the front surface of the n⁺ semiconductor substrate 51. Hereinafter, a layer-stacked body having the n⁻ semiconductor layer 52 stacked on the n⁺ semiconductor substrate 51 will be referred to as “semiconductor base substrate”. An oxide film that is an insulating film 54 to be a protective film is generally used as the mask member. The n⁺ semiconductor substrate 51 acts as an n⁺ cathode layer 55 and the n⁻ semiconductor layer 52 acts as an n⁻ drift layer 56.

In FIG. 9, (2) is a p⁺ semiconductor layer formation process (step S82). A p⁺ anode layer 57, which is a p⁺ semiconductor layer, is selectively disposed in a surface layer of the n⁻ semiconductor layer 52 by ion-implanting a p-type impurity from the surface of the n⁻ semiconductor layer 52 through the opening 53 of the insulating film 54 and by performing a thermal diffusion process.

In FIG. 9, (3) is a platinum film formation process (step S83). The platinum atoms 61 to be the lifetime killer are caused to adhere to the surface of the p⁺ anode layer 57 exposed in the opening 53 of the insulating film 54 from the front surface side of the base substrate using vapor deposition or sputtering. At this process, the platinum atoms 61 adhere to and cover the surface of the insulating film 54 that acts as the mask member covering portions other than the p⁺ anode layer 57 on the surface of the n⁻ semiconductor layer 52.

In FIG. 9, (4) is a platinum diffusion process (step S84). Thermal treatment at a temperature of 800 degrees C. or higher is executed to diffuse the platinum atoms 61 in the n⁺ cathode layer 55, the n⁻ drift layer 56, and the p⁺ anode layer 57. At this process, the platinum atoms 61 are also diffused into the insulating film 54.

In FIG. 9, (5) is an electrode formation process (step S85). The front surface electrode 62 contacting the p⁺ anode layer 57 is disposed to be embedded in the opening 53 of the insulating film 54 and the back surface electrode 63 is disposed on the back surface of the n⁺ semiconductor substrate 51. In this manner, the p-i-n diode 500 having the lifetime killer introduced thereinto is completed.

Excess carriers accumulated in the n⁻ drift layer 56 quickly disappear due to the introduction of the lifetime killer. This quick disappearance reduces the reverse recovery current IRR and shortens the reverse recovery time trr to establish the p-i-n diode 500 for which the switching speed is high.

At the platinum diffusion process (step S84), the platinum atoms are diffused through the silicon lattice, and are diffused in the overall silicon crystal in a short time at a diffusion temperature from about 800 degrees C. to about 1,000 degrees C. to establish an equilibrium state. The platinum atoms in the lattice are disposed at the silicon lattice location through lattice vacancies of the silicon crystal, or are replaced by silicon atoms at the lattice location, to be stabilized as a platinum atom at the lattice location. It is considered that the platinum atoms at the lattice locations act as the lifetime killer or acceptors. As depicted in FIG. 10B, because the lattice vacancy density is generally high at the surface of a silicon wafer, it is known that the density of the platinum at the lattice location takes a U-shaped distribution (a bathtub curve) having high values near the surface.

The relation between the platinum concentration distribution and the electric property of the diode is as follows. The platinum atoms 61 diffused inside the silicon crystal have a high diffusion coefficient and are diffused in the overall silicon crystal in the thickness direction thereof. Because the platinum atoms tend to be segregated in the surface of the silicon crystal, the platinum concentration becomes high especially in the n⁺ cathode layer 51 and the p⁺ anode layer 57. In contrast, the platinum concentration becomes low in the n⁻ drift layer 56 compared to that of the n⁺ anode layer 57. Because the platinum concentration is high near the border between the p⁺ anode layer 57 and the n⁻ drift layer 56, the reverse recovery current IRR (including a peak value IRP of the reverse recovery current IRR) is small and the reverse recovery time trr is short.

According to one method, platinum atoms are diffused not from the base substrate front surface side to be an element disposition region but from the base substrate back surface side (the back surface of the semiconductor substrate) (conventional manufacturing process 2). FIG. 11 is a flowchart of an overview of another example of a method of manufacturing a conventional semiconductor device. FIG. 11 depicts a process step of introducing platinum atoms to be the lifetime killer from the back surface of the base substrate in the manufacturing process of a p-i-n diode 600 of FIGS. 12A and 12B. FIGS. 12A and 12B are explanatory diagrams of a state in the course of the manufacturing process of the conventional p-i-n diode 600. FIG. 12A is a cross-sectional diagram of the conventional p-i-n diode 600 and FIG. 12B is a distribution diagram of the platinum concentration of the semiconductor base substrate. FIG. 12A also depicts a state where a platinum paste 60 is applied to a surface (a back surface of the n⁺ semiconductor substrate 51) 55a of the n⁺ cathode layer 55. The portions to be disposed at subsequent process steps (the front surface electrode 62 to be the anode electrode, and the back surface electrode 63 to be the cathode electrode) are depicted by dotted lines in the cross-sectional diagram using solid lines to depict the state in the course of the manufacturing process.

In FIG. 11, (1) is a mask member formation process (step S91). A mask member 54 having an opening 53 is disposed on a surface of the n⁻ semiconductor layer 52 disposed on the front surface of the n⁺ semiconductor substrate 51. An oxide film that is the insulating film 54 to be a protective film is generally used as the mask member. The n⁺ semiconductor substrate 51 acts as the n⁺ cathode layer 55 and the n⁻ semiconductor layer 52 acts as the n⁻ drift layer 56. In FIG. 11, (2) is a p⁺ semiconductor layer formation process (step S92). The p⁺ anode layer 57 that is a p⁺ semiconductor layer is selectively disposed in the surface layer of the n⁻ semiconductor layer 52 by ion-implanting a p-type impurity from the surface of the n⁻ semiconductor layer 52 through the opening 53 of the insulating film 54 and by performing a thermal diffusion process.

In FIG. 11, (3) is a platinum paste application process (step S93). A platinum paste 60 is applied to the surface (the back surface of the n⁺ semiconductor substrate 51) 55a of the n⁺ cathode layer 55. The platinum paste 60 is formed in a paste produced from silica (SiO₂) that includes platinum.

In FIG. 11, (4) is a platinum diffusion process (step S94). Thermal treatment at a temperature of 800 degrees C. or higher is executed to diffuse the platinum atoms 61 in the n⁺ cathode layer 55, the n⁻ drift layer 56, and the p⁺ anode layer 57. At this step, the platinum atoms 61 are also diffused in the insulating film 54.

In FIG. 11, (5) is an electrode formation process (step S95). The front surface electrode 62 that contacts the p⁺ anode layer 57 is disposed to be embedded in the opening 53 of the insulating film 54 and the back surface electrode 63 that contacts the n⁺ cathode layer 55 is disposed on the back surface of the base substrate. In this manner, the p-i-n diode 600 having the lifetime killer introduced thereinto is completed.

In Japanese Laid-Open Patent Publication No. 2008-4704, argon (Ar), which is an inert element, is first implanted into a semiconductor wafer prior to diffusion of a heavy metal into the semiconductor wafer. The implantation of argon is executed from the semiconductor wafer surface on a position at which a pn junction is formed in the semiconductor wafer. The diffusion of the heavy metal is thereafter executed. Due to the ion implantation of argon, an amorphous structure is formed in the surface layer of the semiconductor wafer and the diffusion of the heavy metal evenly takes place without any bias due to the amorphous structure. An effect is described in that the lifetime of the minority carriers is therefore evenly shortened in the wafer.

Japanese Laid-Open Patent Publication No. 2003-282575 describes that, after diffusing a heavy metal in a semiconductor substrate, electrically charged particles are applied to the semiconductor substrate, thermal treatment is further applied at 650 degrees C. or higher, a predetermined low lifetime region stable even at a high temperature is thereby disposed in the semiconductor substrate. Japanese Laid-Open Patent Publication No. 2003-282575 also describes that no restriction is thereafter imposed on any thermal treatment or temperature to be used in the subsequent wafer processes, or the manufacturing steps each at a temperature up to 650 degrees C.

Japanese Laid-Open Patent Publication No. H9-260686 describes a case where, to realize a high speed operation in a semiconductor rectifier device having a p/n⁻/n⁺ substrate structure, especially, in a switching element, a lifetime killer such as platinum, gold, or the like is introduced therein using diffusion. Especially, recombination centers are formed by diffusing gold or platinum and recombination centers are further formed locally by applying protons, helium, or deuterium to the n⁻ layer from the back surface of the substrate. Japanese Laid-Open Patent Publication No. H9-260686 describes that a proper relation between a forward direction voltage drop and a reverse recovery property is thus obtained.

Japanese Laid-Open Patent Publication No. 2012-38810 describes a method according to which lattice vacancies are formed by introducing lattice defects to set the concentration of platinum as an acceptor to be high in the uppermost surface layer, and the action of platinum as the acceptor is enhanced by displacing the position of platinum from interstitial positions to lattice locations.

In Japanese Laid-Open Patent Publication No. 2008-4704, however, platinum atoms are evenly diffused in the depth direction of the semiconductor substrate. The even diffusion of the platinum atoms in the depth direction of the semiconductor substrate causes the carrier concentration distribution (electrons and holes) during energization to be high also on the p-type anode layer side and it has been confirmed that a problem arises in that hard recovery occurs. The “hard recovery” refers to phenomena such as an increase of the overshoot voltage between the cathode electrode and the anode electrode during reverse recovery exceeding the element breakdown voltage, in addition to an increase of the reverse recovery current IRR.

### SUMMARY OF THE INVENTION

According to one aspect of the present invention, a semiconductor device includes a first semiconductor layer of a first conductivity type; a second semiconductor layer of a second conductivity type and disposed in a surface layer of a first surface of the first semiconductor layer, the second semiconductor layer having an impurity concentration that is higher than that of the first semiconductor layer; and an argon introduced region including argon and disposed at a predetermined depth to have a thickness that is less than that of the second semiconductor layer from a pn junction between the first semiconductor layer and the second semiconductor layer toward a first surface side. Platinum is diffused from the first semiconductor layer to the second semiconductor layer. The platinum has a platinum concentration distribution that has a maximal concentration in the argon introduced region.

In the semiconductor device, the predetermined depth is a position at which a value obtained by integrating an impurity concentration of the second semiconductor layer from the pn junction toward the first surface is a critical integral concentration of the second semiconductor layer.

In the semiconductor device, a length from the pn junction toward the first surface side to the predetermined depth is a diffusion length of a first conductivity type carrier in the second semiconductor layer.

According to another aspect of the present invention, a method of manufacturing a semiconductor device includes selectively disposing a second semiconductor layer of a second conductivity type and having an impurity concentration that is higher than that of a first semiconductor layer of a first conductivity type, in a surface layer of a first surface of the first semiconductor layer; disposing an argon introduced region that includes argon, at a predetermined depth to have a thickness that is less than that of the second semiconductor layer from a pn junction between the first semiconductor layer and the second semiconductor layer toward the first surface, by ion implanting argon from the first surface; and diffusing platinum inside the second semiconductor layer from a second surface of the first semiconductor layer so as to localize the platinum in the argon introduced region.

In the method of manufacturing a semiconductor device, the platinum is in a paste form and applied to the second surface. The platinum is heat treated so as to be diffused inside the second semiconductor layer and localized in the argon introduced region.

In the method of manufacturing a semiconductor device, the platinum is heat treated at a temperature ranging from 800 to 1,000 degrees C.

In the method of manufacturing a semiconductor device, a range of the argon is positioned so as to be in a range from a depth that is ½ of a depth of the second semiconductor layer from the first surface to a depth of the pn junction.

In the method of manufacturing a semiconductor device, a range of the argon is adjusted by acceleration energy of the ion implanting of the argon.

In the method of manufacturing a semiconductor device, the second semiconductor layer is disposed at a depth ranging from 1 to 10 μm from the first surface, and the acceleration energy of the ion implanting of the argon ranges from 0.5 to 30 MeV.

In the method of manufacturing a semiconductor device, the acceleration energy of the ion implanting of the argon is adjusted so that the range of the argon is positioned between the pn junction and a position at which a value obtained by integrating an impurity concentration of the second semiconductor layer from the pn junction toward the first surface is a critical integral concentration of the second semiconductor layer.

In the method of manufacturing a semiconductor device, the second semiconductor layer is disposed by disposing on the first surface, a mask member that has an opening exposing a portion corresponding to a region having the second semiconductor layer disposed therein, and diffusing a second conductivity type impurity that is ion-implanted from the opening of the mask member.

In the method of manufacturing a semiconductor device, the mask member is disposed to have a thickness by which the argon ion-implanted does not pass beyond the mask member.

In the method of manufacturing a semiconductor device, a resist film or an insulating film is disposed as the mask member.

In the method of manufacturing a semiconductor device, boron is ion-implanted as the second conductivity type impurity.

In the method of manufacturing a semiconductor device, the second semiconductor layer is disposed as a guard ring layer constituting a voltage breakdown structure in a terminal region surrounding a periphery of one of an anode layer of a pn junction diode, an anode layer of a body diode of an insulated gate field effect transistor, a base layer of an insulated gate bipolar transistor, an anode layer of a diode portion of a reverse-conducting insulated gate bipolar transistor, and an active region.

In the semiconductor device, the second semiconductor layer is a p base layer of a metal oxide semiconductor field effect transistor (MOSFET).

The semiconductor device is one of a metal oxide semiconductor field effect transistor (MOSFET), an insulated gate bipolar transistor (IGBT), and a reverse-conducting insulated gate bipolar transistor (RC-IGBT).

In the semiconductor device, the second semiconductor layer is a p guard ring.

In the semiconductor device, the second semiconductor layer includes a Schottky contact surface in which the first semiconductor layer forms a Schottky contact with a front surface electrode. A platinum concentration of the Schottky contact surface is lower than that of the argon introduced region.

In the method of manufacturing a semiconductor device, the platinum is localized to have a platinum concentration distribution that has a maximal concentration in the argon introduced region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a flowchart of an overview of a method of manufacturing a semiconductor device according to a first embodiment;

FIG. 2A is a cross-sectional diagram of a semiconductor device 100 according to the first embodiment;

FIG. 2B is a distribution diagram of platinum concentration along cut line A-A line of FIG. 2A;

FIG. 2C is a distribution diagram of argon concentration along cut A-A line of FIG. 2A;

FIG. 3A is a cross-sectional diagram of a p-i-n diode 100a;

FIG. 3B is a distribution diagram of the platinum concentration along cut line A-A line of FIG. 3A;

FIG. 4 is a property diagram of an electric property of the p-i-n diode 100a according to Example 2;

FIG. 5 is a cross-sectional diagram of a semiconductor device manufactured using a method of manufacturing a semiconductor device according to a second embodiment of the present invention;

FIG. 6 is a cross-sectional diagram of a semiconductor device manufactured using a method of manufacturing a semiconductor device according to a third embodiment of the present invention;

FIG. 7 is a cross-sectional diagram of a semiconductor device manufactured using a method of manufacturing a semiconductor device according to a fourth embodiment of the present invention;

FIG. 8 is a cross-sectional diagram of a semiconductor device manufactured using a method of manufacturing a semiconductor device according to a fifth embodiment of the present invention;

FIG. 9 is a flowchart of an overview of a method of manufacturing a conventional semiconductor device;

FIG. 10A is a cross-sectional diagram of a conventional p-i-n diode 500;

FIG. 10B is a distribution diagram of the platinum concentration of a semiconductor base substrate;

FIG. 11 is a flowchart of an overview of another example of a method of manufacturing a conventional semiconductor device;

FIG. 12A is a cross-sectional diagram of a conventional p-i-n diode 600;

FIG. 12B is a distribution diagram of the platinum concentration of the semiconductor base substrate;

FIGS. 13A and 13B are property diagrams of an impurity concentration distribution of a semiconductor device manufactured using the method of manufacturing a semiconductor device according to the first embodiment of the present invention;

FIG. 14 is a property diagram of an ion implantation property of argon into a silicon substrate;

FIG. 15A is a cross-sectional diagram of a semiconductor device manufactured using a method of manufacturing a semiconductor device according to a sixth embodiment of the present invention; and

FIG. 15B is a distribution diagram of the platinum concentration along cut line A-A of FIG. 15A.

### DETAILED DESCRIPTION OF THE INVENTION

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, identical constituent elements will be given the same reference numerals and will not be repeatedly described. Further, in the embodiments, a first conductivity is assumed to be an n type and a second conductivity is assumed to be a p type.

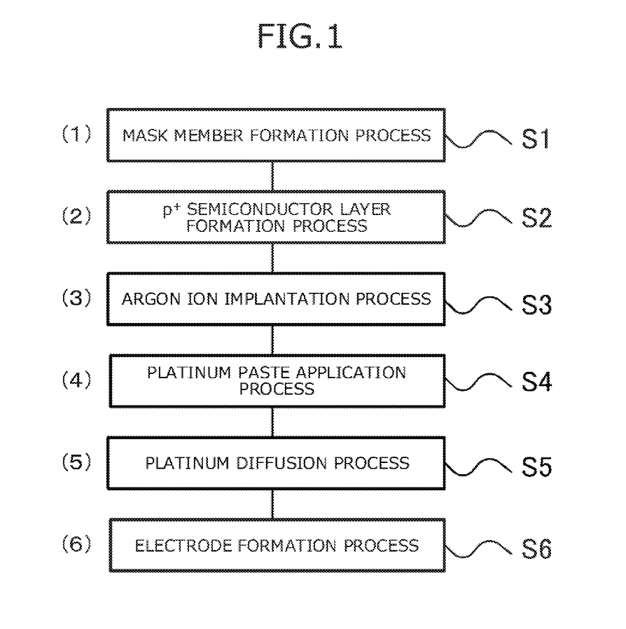

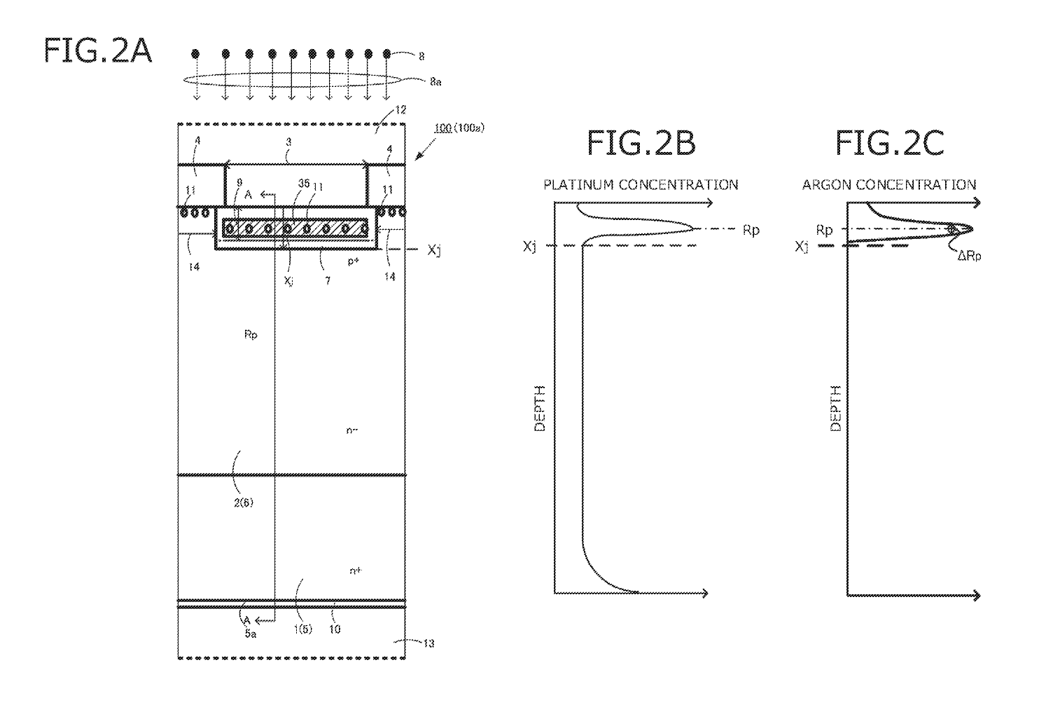

The method of manufacturing a semiconductor device according to the first embodiment will be described. FIG. 1 is a flowchart of an overview of the method of manufacturing a semiconductor device according to the first embodiment. FIG. 1 depicts a manufacturing process of a p-i-n diode 100a that is a semiconductor device 100 according to the first embodiment of FIGS. 2A, 2B, and 2C. FIGS. 2A, 2B, and 2C are explanatory diagrams of a state in the course of the manufacturing process of the semiconductor device 100 according to the first embodiment. FIG. 2A is a cross-sectional diagram of the semiconductor device 100 according to the first embodiment. FIG. 2B is a distribution diagram of the platinum concentration along cut line A-A line of FIG. 2A. FIG. 2C is a distribution diagram of the argon concentration along cut A-A line of FIG. 2A. The vertical axis of FIG. 2B and FIG. 2C represents the depth from the surface of a p⁺ anode layer 7 (the front surface of a base substrate) to the inside of the semiconductor base substrate, and the horizontal axis represents the concentration. The scale of the horizontal axis is taken according to the common logarithm in both FIGS. 2B and 2C. FIG. 2A also depicts ion implantation 8a of argon (Ar), a defective layer 9, a platinum paste 10 applied to the back surface of the base substrate, and the like. Portions disposed in the subsequent manufacturing process steps (a front surface electrode 12 to be the anode electrode and a back surface electrode 13 to be the cathode electrode) are depicted using dotted lines in the cross-sectional diagram using solid lines to depict the state in the course of the manufacturing process.

Description will be made with reference to FIGS. 1 and 2A. Hereinafter, each number in parentheses indicates the numbers in parentheses of FIG. 1 and represents the order of the process steps.

In FIG. 1, (1) is a mask member formation process (step S1). An insulating film 4 to be a mask member having an opening 3 and also to be a protective film is formed on a surface (the surface on the opposite side with respect to an n⁺ semiconductor substrate 1 side) of an n⁻ semiconductor layer 2 disposed on the front surface of the n⁺ semiconductor substrate 1. An oxide film is generally used as the insulating film 4. The insulating film 4 is formed to have a thickness by which argon 8 to be ion-implanted 8a at an argon ion implantation step described later does not penetrate the insulating film 4. The n⁺ semiconductor substrate 1 acts as an n⁺ cathode layer 5 and the n⁻ semiconductor layer 2 acts as an n⁻ drift layer 6. FIG. 2A depicts a case where an epitaxial-grown layer grown on the front surface of the n⁺ semiconductor substrate 1 is used as the n⁻ semiconductor layer 2. When the components of an element structure are formed using a diffusion method, the n⁺ cathode layer 5 is disposed using diffusion in the surface layer of the overall back surface of the n⁻ semiconductor substrate and the p⁺ anode layer 7 is selectively disposed using diffusion (as described later) in the surface layer of the front surface of the n⁻ semiconductor substrate. The portion of the n⁻ semiconductor substrate having the n⁺ cathode layer 5 and the p⁺ anode layer 7 not disposed therein becomes the n⁻ drift layer 6. Hereinafter, the region from the n⁺ cathode layer 5 to the n⁻ semiconductor layer 2 and the p⁺ anode layer 7 will be referred to as “semiconductor base substrate”.

The n⁺ semiconductor substrate 1 is a semiconductor substrate having, for example, arsine (As) doped therein, and the n⁻ semiconductor layer 2 is a semiconductor layer is epitaxially grown on the n⁺ semiconductor substrate 1 and, for example, is doped with phosphorus (P). The thickness of the n⁺ semiconductor substrate 1 is about 500 μm and the impurity concentration thereof is about 2×10¹⁹ cm⁻³. The thickness of the n⁻ semiconductor layer 2 to be the n⁻ drift layer 6 is about 8 μm and the impurity concentration thereof is about 2×10¹⁵ cm⁻³. The oxide film to be the insulating film 4 is formed using thermal oxidation and the thickness of the insulating film 4 is about 1 μm. The semiconductor base substrate may be a bulk-cutout substrate. The bulk-cutout substrate is a substrate obtained by being sliced from an ingot of silicon or the like produced using, for example, a Czochralski (CZ) method, a magnetic field applied CZ (MCZ) method, a floating zone (FZ) method, or the like to be mirror-finished. When, for example, an MCZ substrate is used as the semiconductor base substrate, the n-type impurity concentration of the MCZ substrate is used as the impurity concentration of the n⁻ drift layer 6. The n⁺ cathode layer 5 may be disposed by grinding the back surface of the MCZ substrate by back-grinding, etching, or the like to reduce the thickness of the MCZ substrate and, with respect to the ground surface, thereafter executing ion implantation and annealing (thermal treatment, laser annealing, or the like) for activation.

In FIG. 1, (2) represents a p⁺ semiconductor layer formation process (step S2). A p-type impurity is ion-implanted from the surface of the n⁻ semiconductor layer 2 through the opening 3 of the insulating film 4 to selectively dispose the p⁺ anode layer 7 that is a p⁺ semiconductor layer, in the surface layer of the n⁻ semiconductor layer 2 using thermal diffusion. When, for example, boron (B) is used as a dopant, the dose amount of the ion implantation to dispose the p⁺ anode layer 7 is, for example, about 1×10¹³ cm⁻²to 1 (1.3×10¹² cm⁻² to 1×10¹⁴ cm⁻²) and the acceleration energy may be, for example, about 100 keV (30 keV to 300 keV). The diffusion temperature may be about 1,000 degrees C. or higher (1,000 degrees C. to 1,200 degrees C.). The diffusion depth (the thickness) of the p⁺ anode layer 7 is thereby set to be, for example, about 3 μm (2 μm to 5 μm). The surface concentration of the anode layer 7 is set to be, for example, about 2×10¹⁶ cm⁻³ (1×10¹⁶ cm⁻³ to 1×10¹⁷ cm⁻³).

In FIG. 1, (3) is an argon ion implantation process (step S3). The defective layer (an argon introduced region) 9 is disposed in the p⁺ anode layer 7 by ion-implanting 8a argon 8 (element symbol: “Ar”) from the base substrate front surface (the surface of the p⁺ anode layer 7) using the insulating film 4 as a mask. For example, as depicted in FIG. 2C, in the defective layer 9, argon atoms have a peak value as the maximal concentration thereof at the range Rp of the argon 8 and argon atoms of a concentration of about half of the maximal concentration are distributed within a width of the straggling ΔRp centered about the range Rp. The position where the concentration distribution of the argon atoms becomes Rp+ΔRp on the cathode side of the defective layer 9 may be shallower than a diffusion depth Xj of the p⁺ anode layer 7. The range Rp of the argon 8 is set to be in a range equal to or larger than ½ of the diffusion depth Xj of the p⁺ anode layer 7 and substantially equal to or smaller than the diffusion depth Xj of the p⁺ anode layer. In a case where the diffusion depth Xj of the p⁺ anode layer 7 is set to be 1 μm to 10 μm, the range Rp of the argon 8 may be set to be in the above range when the acceleration energy PAr of the ion implantation 8a of the argon 8 is set to be in a range from 0.5 MeV to 30 MeV. When the diffusion depth Xj of the p⁺ anode layer 7 is, for example, 5 μm, the acceleration energy of the ion implantation 8a of the argon 8 is advantageously set to be about 4 MeV to 10 MeV. The relation between the range Rp of the argon 8 or the acceleration energy of the ion implantation 8a of the argon 8, and the diffusion depth Xj of the p⁺ anode layer 7 will be described later.

In FIG. 1, (4) is a platinum paste application process (step S4). A platinum paste 10 is applied to the surface (the back surface of the n⁺ semiconductor substrate 1) 5a of the p⁺ cathode layer 5. The platinum paste 10 is formed in a paste produced from silica (SiO₂) that includes platinum atoms 11. Because the platinum atoms 11 are diffused from the surface 5a of the n⁺ cathode layer 5, the platinum atoms 11 are not diffused in the insulating film 4 on the front surface side of the base substrate. Though the platinum atoms 11 are depicted using circles in FIG. 2, the circles indicate the presence of the platinum atoms 11 for descriptive purpose and the circles do not indicate that the actual platinum atoms 11 are present exactly at the positions of the circles. The actual platinum atoms 11 distribute to a depth, having a predetermined impurity concentration and a predetermined width in a platinum localization region 35 that is, in FIG. 2, hatched by slashes, and also distribute at an impurity concentration lower than that of the platinum localization region 35 in the overall semiconductor base substrate. In particular, as depicted in FIG. 2B, in the depth direction of the semiconductor base substrate, the platinum atoms 11 present having the highest peak in the portion substantially covered by the range Rp of the argon 8 of the defective layer 9, and distribute in a substantially flat concentration distribution except an increase thereof at the border with the back surface electrode 13.

In FIG. 1, (5) is a platinum diffusion process (step S5). The platinum atoms 11 are diffused in the overall semiconductor base substrate in the depth direction into the p⁺ anode layer 7 from the back surface of the base substrate through the n⁺ cathode layer 5 and the n⁻ drift layer 6 by executing thermal treatment at a temperature, for example, substantially equal to or higher than about 800 degrees C. or higher. At this step, in the defective layer 9 disposed by the ion implantation 8a of the argon 8 at step S3, the platinum atoms 11 are segregated centered around a region having the argon atoms localized therein (Rp±ΔRp). This is because many point defects such as vacancies and divacancies are formed due to the ion implantation 8a of the argon 8 and the platinum atoms 11 gather at the point defects. The platinum atoms 11 thereby occupy the locations at which the point defects are formed and, as a result, the point defects at the locations occupied by the platinum atoms 11 disappear while the argon atoms remain at locations such as interstitial locations of the silicon atoms. Consequently, the platinum atoms 11 are gathered to the defective layer 9 and the platinum atoms 11 are localized in the region that has the argon atoms localized therein. On the other hand, as depicted in FIG. 2A, the argon 8 is not ion-implanted 8a into the surface (the front surface) covered by the insulating film 4 of the semiconductor base substrate and the platinum atoms 11 are therefore segregated and localized in the surface layer of the front surface of the semiconductor base substrate.

The temperature of the thermal treatment at the platinum diffusion step to be step S5 may be, for example, 800 degrees C. to 1,000 degrees C. The reason for this is as follows. When the temperature of the thermal treatment at the platinum diffusion step exceeds, for example, 1,000 degrees C. as described in Japanese Laid-Open Patent Publication No. 2008-4704, the diffusion speed of the platinum atoms 11 is high and the platinum atoms 11 cannot be captured in the defective layer 9 formed by the ion implantation 8a of the argon 8. When the platinum atoms 11 cannot be captured by the defective layer 9, the platinum atoms 11 are diffused in the overall n⁻ drift layer 6 and the concentration distribution of the platinum atoms 11 is expanded to weaken the localization thereof. When the temperature of the thermal treatment at the platinum diffusion step is 800 degrees C. or less, the platinum atoms 11 are not diffused in the overall semiconductor base substrate. Thus, temperature of the thermal treatment at the platinum diffusion step may be about 900 degrees C.

In FIG. 1, (6) is an electrode formation process (step S6). The front surface electrode 12 that contacts the p⁺ anode layer 7 is disposed to be embedded in the opening 3 of the insulating film 4 and the back surface electrode 13 that contacts the n⁺ cathode layer 5 is disposed on the back surface of the base substrate. In this manner, the semiconductor device 100 is completed that is the p-i-n diode 100a having the platinum atoms 11 to be the lifetime killer introduced therein being localized in the p⁺ anode layer 7.

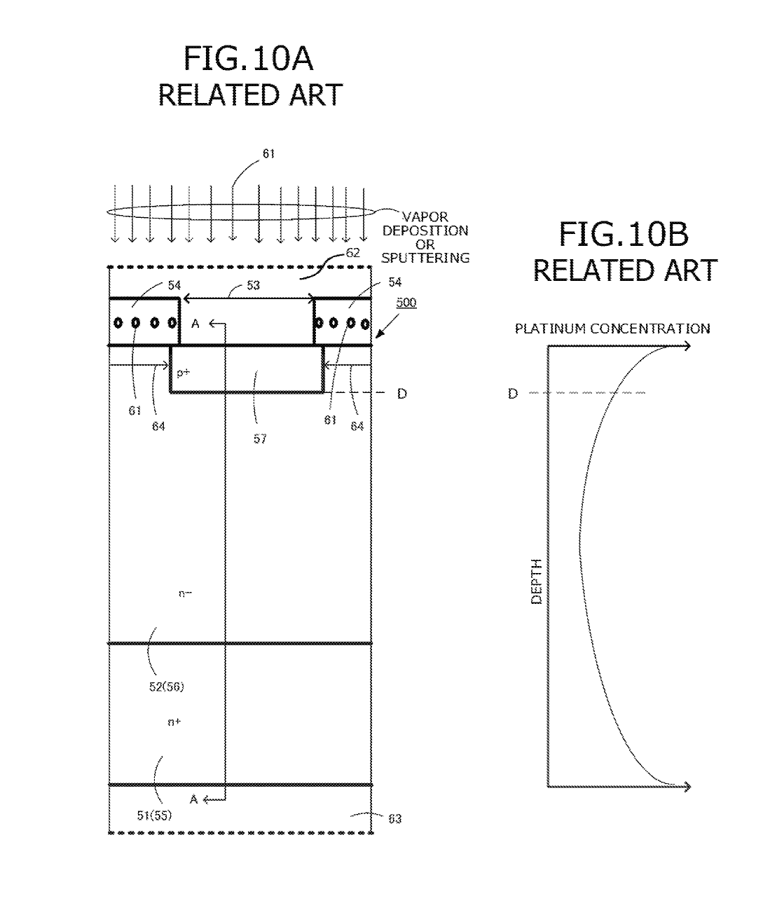

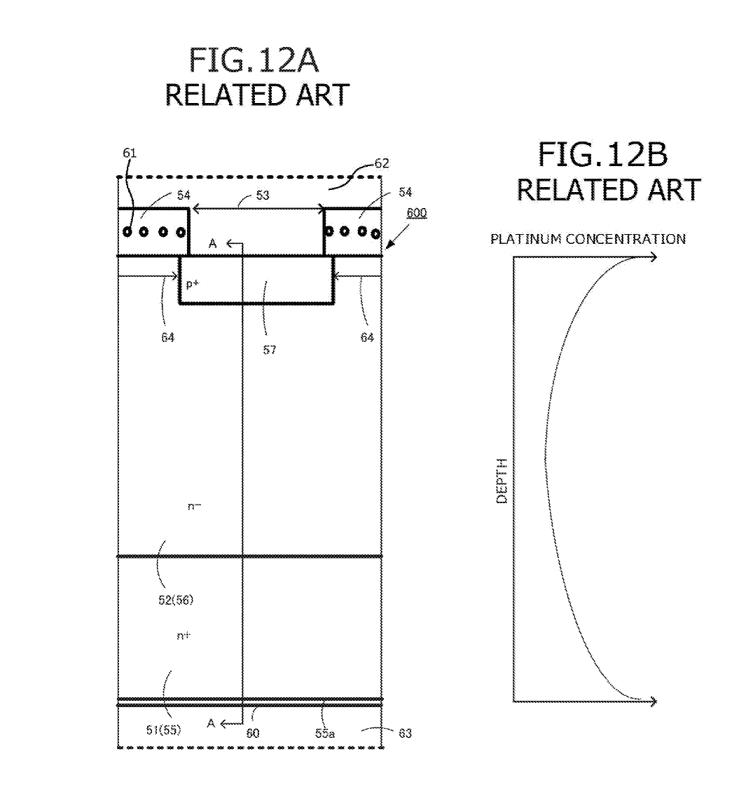

Based on the above process steps, the platinum concentration becomes maximal in the region having the argon atoms localized therein in the defective layer 9 as described (FIG. 2B). The platinum atoms 11 are localized in the portion on the cathode side of the defective layer 9 due to the ion implantation 8a of the argon 8, and the degree of segregation thereof is reduced in the surface layer on the front surface side of the base substrate of the p⁺ anode layer 7. Because the argon 8 is not ion-implanted 8a into the portion that contacts the insulating film 4 of the front surface of the base substrate (the surface of the n⁻ drift layer 6), the platinum atoms 11 are segregated in the surface layer of the front surface of the semiconductor base substrate similarly to the conventional case (FIGS. 10 and 12). Here, the region having the p⁺ anode layer 7 disposed therein is assumed as an “active region” and the outer peripheral portion surrounding the periphery of the active region is assumed as an “edge termination region”, the lifetime of the surface layer of the front surface of the semiconductor base substrate is shorter in the edge termination region than in the active region. During the reverse recovery, concentration of carriers (holes and electrons) at the edge termination region is therefore mitigated and an effect is achieved in that the reverse recovery tolerance is improved. The “active region” refers to the region through which current flows during the ON state (driving current). The “edge termination region” refers to the region that mitigates the electric field on the front surface side of the base substrate of the drift layer to maintain the breakdown voltage.

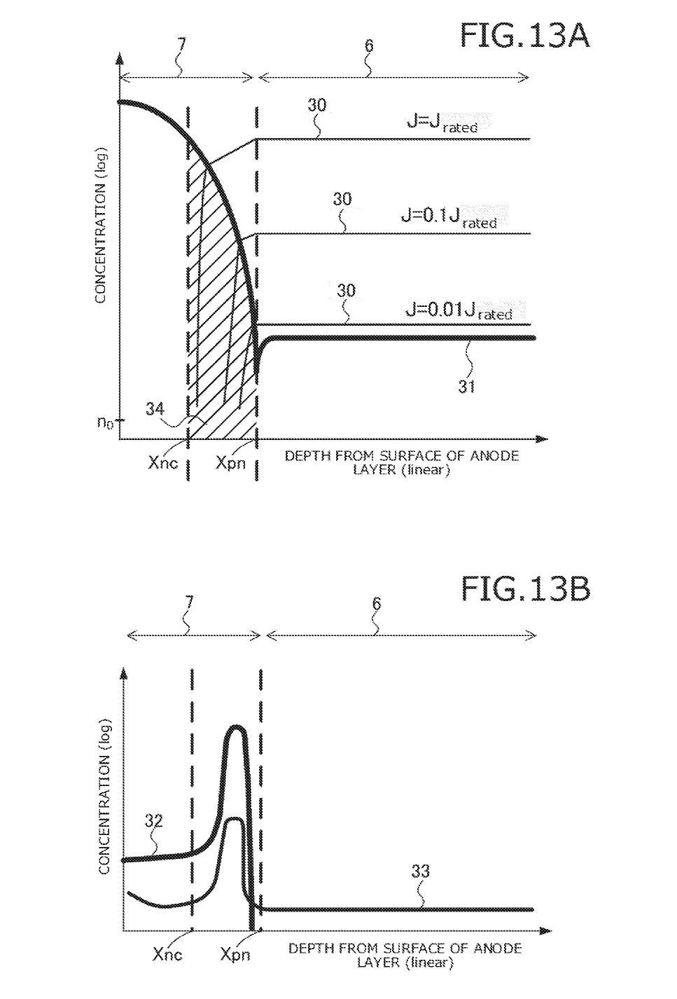

The relation will be described among the diffusion depth Xj of the p⁺ anode layer 7, the range Rp of the ion implantation 8a of the argon 8, and the localization location of the platinum atoms 11. FIGS. 13A and 13B are property diagrams of the impurity concentration distribution of the semiconductor device manufactured using the method of manufacturing a semiconductor device according to the first embodiment of the present invention. The horizontal axis of FIG. 13A represents the depth from the surface of the p⁺ anode layer 7 (the front surface of the base substrate) into the inside of the semiconductor base substrate, and the vertical axis represents the concentration of the doping and the electrons. The horizontal axis of FIG. 13B corresponds to the horizontal axis of FIG. 13A and the vertical axis represents an argon concentration 32 and a platinum concentration 33. The scale of the vertical axis is taken according to the common logarithm in both of FIGS. 13A and 13B. FIG. 13A depicts a doping concentration 31 (the net doping concentration) and an electron density 30 obtained when the p-i-n diode 100a is energized in the forward direction. When a forward direction voltage is applied to the p-i-n diode 100a, holes are injected from the p⁺ anode layer 7 into the n⁺ cathode layer 5 on the side of the back surface of the base substrate through the n⁻ drift layer 6 and electrons are injected from the n⁺ cathode layer 5 into the p⁺ anode layer 7 through the n⁻ drift layer 6. In particular, the injection efficiency of the holes at the front surface electrode 12 (the anode electrode) depends on the diffusion length of the electrons to be injected into the p⁺ anode layer 7. As depicted in FIG. 13A, when the value of a forward direction current IF becomes 1%, 10%, and 100% of that of a rated current density J_{rated} (for example, 300 A/cm²), the electron density 30 has a density distribution that is substantially flat in the n⁻ drift layer 6 and steeply reduced near the border with the n⁻ drift layer 6 of the p⁺ anode layer 7 to reach a thermal equilibrium density n₀. In this case, when the diffusion length of the electrons entering the p⁺ anode layer 7 is shortened, the injection efficiency of the holes is reduced and a reverse recovery current IRR can be reduced.

In the p⁺ anode layer 7, a region from a position Xpn of the pn junction between the p⁺ anode layer 7 and the n⁻ drift layer 6 (the same value as that of the diffusion depth Xj) to the position at which the electron density 30 reaches the thermal equilibrium density n₀ will be referred to as “electron entering region 34” and the platinum atoms 11 are localized within the range of the electron entering region 34. To establish this, at a manufacturing step (step S3), the range Rp of the ion implantation 8a of the argon 8 is set to be the inside of the electron entering region 34 to localize the argon 8 in the electron entering region 34. Lattice defects, especially, lattice vacancies (such as vacancies and divacancies) are thereby localized in the region having the argon 8 localized therein. When the platinum atoms 11 are diffused at a manufacturing step (step S5), the platinum atoms 11 are captured by the lattice vacancies localized with the argon 8 to be localized. The platinum atoms 11 can be localized in the electron entering region 34.

Because the electron density 30 is varied based on a current density J of the energization, i.e., the electron entering region 34 depends on the current density J. Two points are defined as the equivalent definition of the electron entering region 34. The first point is that the range of the depth (the thickness) of the electron entering region 34 is defined as a diffusion length Ln of electrons from the position Xpn of the pn junction between the p⁺ anode layer 7 and the n⁻ drift layer 6 into the p⁺ anode layer 7. The diffusion length Ln of the electrons is (Dntn)^{0.5}. “Dn” is a diffusion coefficient of the electrons. “tn” is the lifetime of the electrons. The second point is that an integral value is obtained by integrating the doping concentration (the acceptor concentration) of the p⁺ anode layer 7 from the position Xpn of the pn junction between the p⁺ anode layer 7 and the n⁻ drift layer 6 to the front surface side of the base substrate, and a range is defined as the electron entering region 34, that is from the position Xpn to a position Xnc at which the value of integral of the p⁺ anode layer 7 from the position Xpn becomes a critical integral concentration nc (about 1.3×10¹² cm⁻²). When a reverse bias is applied, the depletion layer spreads out from the position Xpn of the pn junction between the p⁺ anode layer 7 and the n⁻ drift layer 6 into the p⁺ anode layer 7. When the reverse bias voltage is increased resulting in the occurrence of avalanche breakdown, the electric field intensity is substantially 2×10⁵ V/cm to 3×10⁵ V/cm for silicon (Si). Consequently, the integral value of the p⁺ anode layer 7 becomes the critical integral concentration nc (about 1.3×10¹² cm⁻²), which is substantially constant and is determined depending on the material of the semiconductor and is, for example, about 1.3×10¹³ cm⁻² for silicon carbide (SiC), a 10-fold value of the above. Gallium nitride has a value on the order of 10¹³ cm² similarly to that of SiC. In the p-i-n diode 100a, the leak current rapidly increases when the overall p⁺ anode layer 7 is depleted, and the depletion of the overall p⁺ anode layer 7, therefore, needs to be prevented when avalanche breakdown occurs. The integral concentration of the p⁺ anode layer 7 is, therefore, set to be higher than the critical integral concentration nc. The overall diffusion depth of the p⁺ anode layer 7 needs to be deeper toward the cathode side than a position (hereinafter, referred to as “critical integral concentration position of the p⁺ anode layer 7”) Xnc at which the integral concentration of the p⁺ anode layer 7 in a direction from the position Xpn of the pn junction between the p⁺ anode layer 7 and the n⁻ drift layer 6 toward the front surface side of the base substrate becomes the critical integral concentration nc. In other words, when the current density J is sufficiently high to substantially be the rated current density, the electrons entering the p⁺ anode layer 7 from the cathode side during the application of the forward bias enter the p⁺ anode layer 7 from the position Xpn of the pn junction with the n⁻ drift layer 6 to at least the critical integral concentration position Xnc of the p⁺ anode layer 7. Consequently, the region from the position Xpn of the pn junction between the p⁺ anode layer 7 and the n⁻ drift layer 6 to the critical integral concentration position Xnc of the p⁺ anode layer 7 may be referred to as the electron entering region 34 and the platinum atoms 11 are localized in this region. To establish this, the range Rp of the ion implantation 8a of the argon 8 is advantageously set to be a region from the position Xpn of the pn junction between the p⁺ anode layer 7 and the n⁻ drift layer 6 to the critical integral concentration position Xnc of the p⁺ anode layer 7.

A value of the acceleration energy PAr of the ion implantation 8a of the argon 8 will be described. To localize the platinum atoms 11 in the electron entering region 34, for example, the acceleration energy PAr of the ion implantation 8a of the argon 8 is advantageously determined such that the range Rp of the argon 8 is positioned in the p⁺ anode layer 7 near the diffusion depth Xj of the p⁺ anode layer 7. For example, the acceleration energy PAr of the ion implantation 8a of the argon 8 is advantageously determined to be in a range of 0.5 MeV to 10 MeV. The dose amount DAr of the ion implantation 8a of the argon 8 may be 1×10¹⁴ cm⁻² to 1×10¹⁶ cm⁻². The reason for this is as follows. When the dose amount DAr of the ion implantation 8a of the argon 8 is less than 1×10¹⁴ cm⁻², the defect amount of the defective layer 9 is excessively small. As a result, the platinum concentration in the platinum localization region 35 becomes excessively low and the reverse recovery current IRR becomes excessively large. When the dose amount DAr of the ion implantation 8a of the argon 8 exceeds 1×10¹⁶ cm⁻², the platinum concentration in the platinum localization region 35 becomes excessively high and a forward voltage drop VF becomes excessively high.

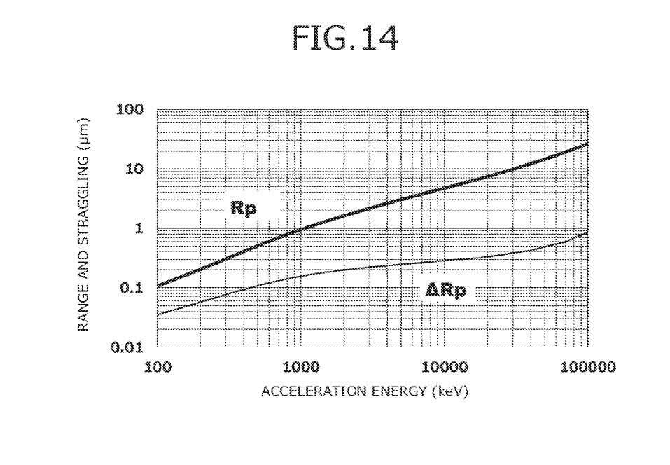

FIG. 14 is a property diagram of an ion implantation property of argon into the silicon substrate. FIG. 14 depicts a dependency property of the range Rp of the argon 8 and the straggling ΔRp of the range Rp (the variation of the range Rp) in the silicon substrate on the acceleration energy PAr of the ion implantation 8a, in the ion implantation 8a of the argon 8. Assuming that the diffusion depth of the p⁺ anode layer 7 is 3.0 μm and the surface concentration is about 2×10¹⁶ cm⁻³, the position at which the integral concentration of the p⁺ anode layer 7 in the direction from the position Xpn of the pn junction between the p⁺ anode layer 7 and the n⁻ drift layer 6 toward the front surface side of the base substrate becomes the critical integral concentration nc is the position at which the integral concentration of the p⁺ anode layer 7 in the direction from the position Xpn toward the front surface side of the base substrate is about 1×10¹⁶ cm⁻³. The critical integral concentration position Xnc of the p⁺ anode layer 7 is about 1.5 μm away from the position Xpn of the pn junction between the p⁺ anode layer 7 and the n⁻ drift layer 6, and about 1.5 μm away from the front surface of the semiconductor substrate (the interface between the p⁺ anode layer 7 and the front surface electrode 12). The electron entering region 34 is therefore positioned within a range of 1.5 μm to 3.0 μm from the interface between the p⁺ anode layer 7 and the front surface electrode 12. In this case, the acceleration energy PAr of the ion implantation 8a of the argon 8, for example, is 2 MeV when the range Rp of the argon 8 is set to be 1.5 μm, and is 5 MeV when the range Rp of the argon 8 is set to be 3.0 μm. The acceleration energy PAr of the ion implantation 8a of the argon 8 may be set to be 2 MeV to 5 MeV.

A lifetime distribution formed when the platinum atoms 11 are localized in the electron entering region 34 will be described. The platinum atoms 11 are gathered (segregated) in the defective layer 9 of the p⁺ anode layer 7 and are localized in the p⁺ anode layer 7 at a high concentration. The lifetime is therefore short in the p⁺ anode layer 7. The platinum atoms 11 are absorbed by the defective layer 9 of the p⁺ anode layer 7 and the platinum concentration in the n⁻ drift layer 6 is therefore low. The lifetime is therefore long in the n⁻ drift layer 6.

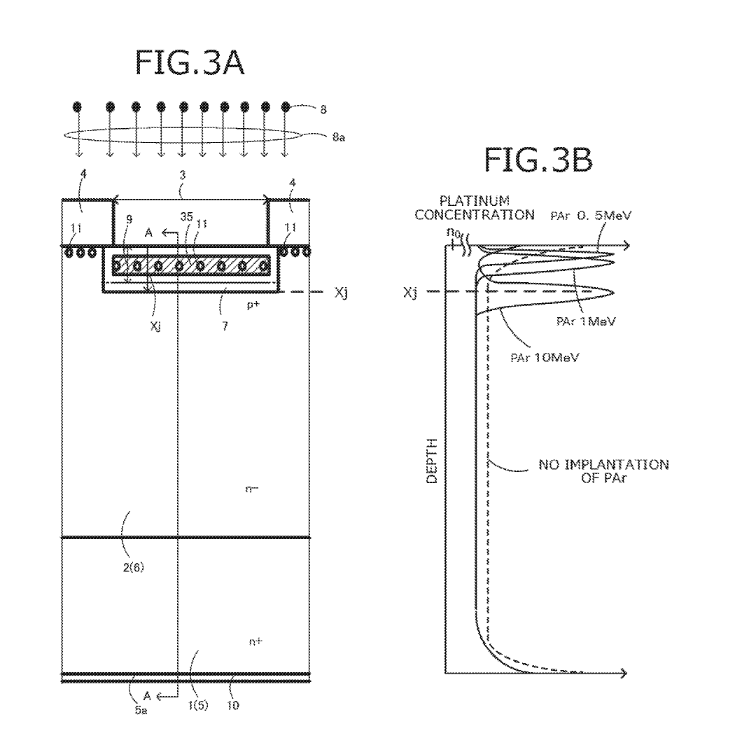

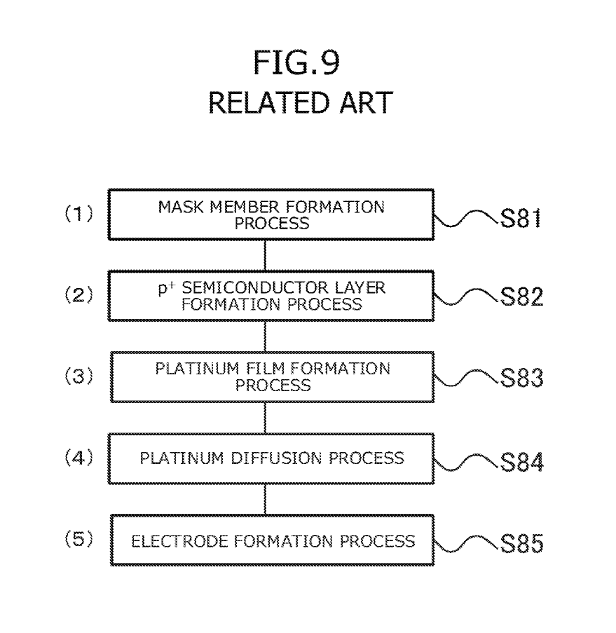

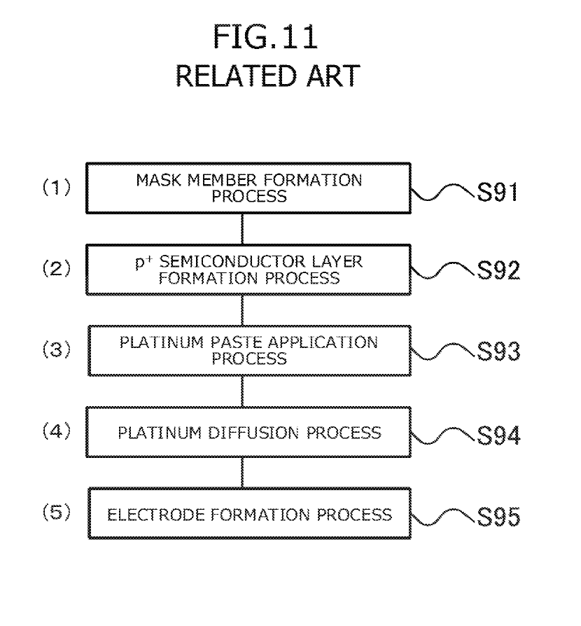

The platinum concentration distribution was verified for cases where the ion implantation 8a of the argon 8 was executed with different values of acceleration energy PAr. FIGS. 3A and 3B are explanatory diagrams of the state in the course of the manufacturing process of the p-i-n diode 100a according to Example 1. FIG. 3A is a cross-sectional diagram of the p-i-n diode 100a, and FIG. 3B is a distribution diagram of the platinum concentration along cut line A-A line of FIG. 3A. In FIG. 3B, distributions of the platinum concentration are indicated by solid lines, that were obtained for the dose amount DAr of 1×10¹⁶ cm⁻² of the ion implantation 8a of the argon 8 and values of the acceleration energy PAr of 0.5 MeV, 1 MeV, and 10 MeV of the ion implantation 8a of the argon 8 (hereinafter, referred to as “Example 1”). On the other hand, a distribution of the platinum concentration is indicated by a dotted line for a conventional case where the argon 8 was not ion-implanted (see FIG. 9 to FIG. 12) (hereinafter, referred to as “Conventional Example”). In Example 1, the range Rp of the argon 8 was set to be shallower than the diffusion depth Xj of the p⁺ anode layer 7. As depicted in FIG. 3B, in Conventional Example, the platinum concentration near the end on the cathode side (the diffusion depth Xj) of the p⁺ anode layer 7 increased as the acceleration energy PAr of the ion implantation 8a of the argon 8 increased, indicating that the lifetime near the diffusion depth Xj of the p⁺ anode layer 7 was shortened. As a result, the peak value IRP of the reverse recovery current IRR was reduced. On the other hand, the platinum concentration was mostly localized in the p⁺ anode layer 7 and the platinum atoms 11 in the n⁻ drift layer 6 were segregated in the region having the argon atoms localized therein of the defective layer 9 formed by the ion implantation 8a of the argon 8. As a result, compared to the distribution of the platinum concentration of Conventional Example having the ion implantation 8a of the argon 8 not executed therein, the platinum concentration in the n⁻ drift layer 6 was reduced. The platinum concentration in the n⁻ drift layer 6 was maintained at a value lower than that of Conventional Example and did not vary even when the acceleration energy PAr of the ion implantation 8a of the argon 8 varied. The lifetime in the n⁻ drift layer 6 was longer in Example 1 compared to that of Conventional Example. In Example 1, therefore, the forward voltage drop VF did not significantly vary even when the acceleration energy PAr of the ion implantation 8a of the argon 8 varied. As a result, the tradeoff between the peak value IRP of the reverse recovery current IRR and the forward voltage drop VF was improved by increasing the acceleration energy PAr of the ion implantation 8a of the argon 8. The realization of soft recovery of the waveform of the reverse recovery current could be facilitated because the platinum concentration was low and the lifetime was long in the n⁻ drift layer 6.

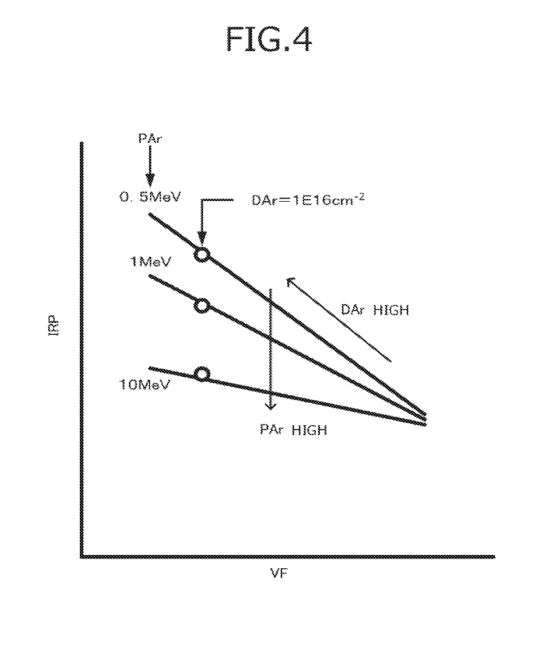

The relation between the peak value IRP of the reverse recovery current IRR and the forward voltage drop VF was verified using the dose amount DAr and the acceleration energy PAr of the ion implantation 8a of the argon 8 as the parameters. FIG. 4 is a property diagram of an electric property of the p-i-n diode 100a according to Example 2. According to the manufacturing process steps of the semiconductor device of the first embodiment, the p-i-n diode 100a was manufactured (hereinafter, referred to as “Example 2”). The dose amount DAr of the ion implantation 8a of the argon 8 was varied in a range of 1×10¹⁴ cm⁻² to 1×10¹⁶ cm⁻² and the acceleration energy PAr of the ion implantation 8a of the argon 8 was varied in a range of 0.5 MeV to 10 MeV. The platinum atoms 11 were introduced from the surface (the surface of the n⁺ semiconductor substrate 1) 5a of the n⁺ cathode layer 5 at a diffusion temperature of 900 degrees C. From the result depicted in FIG. 4, when the dose amount DAr of the ion implantation 8a of the argon 8 increased, the peak value IRP of the reverse recovery current IRR increased and the forward voltage drop VF decreased. This was because, when the dose amount DAr of the ion implantation 8a of the argon 8 was increased, the platinum atoms 11 were absorbed by the defective layer 9 formed in the p⁺ anode layer 7 and the platinum concentration in the n⁻ drift layer 6 decreased. When the acceleration energy PAr of the ion implantation 8a of the argon 8 increased, the peak value IRP of the reverse recovery current IRR moved toward a position to be smaller. This was because, when the acceleration energy PAr of the ion implantation 8a of the argon 8 was increased, the range Rp of the argon 8 was extended to reach a vicinity of the diffusion depth Xj of the p⁺ anode layer 7 and the platinum concentration was increased near the diffusion depth Xj of the p⁺ anode layer 7. The tradeoff was therefore improved between the peak value IRP of the reverse recovery current IRR and the forward voltage drop VF when the acceleration energy PAr of the ion implantation 8a of the argon 8 was increased.

As described, according to the first embodiment, the platinum atoms to be the lifetime killer can be localized in the p anode layer by ion-implanting argon from the front surface of the base substrate into the inside of the p anode layer setting the range to be near the pn junction with the n⁻ drift layer and by thereafter diffusing the platinum atoms from the back surface of the base substrate into the inside of the p anode layer. Localization of the platinum atoms can thereby be prevented near the border of the p anode layer and the front surface electrode. The reverse recovery current can be reduced, the reverse recovery time can be shortened, and the forward voltage drop can be reduced.

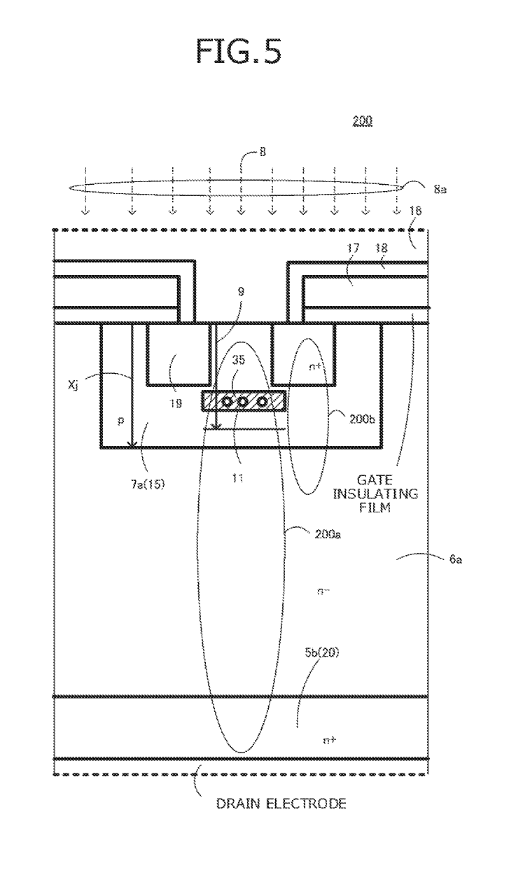

A method of manufacturing a semiconductor device according to the second embodiment will be described. FIG. 5 is a cross-sectional diagram of the semiconductor device manufactured using a method of manufacturing a semiconductor device according to the second embodiment of the present invention. The method of manufacturing a semiconductor device according to the second embodiment is a manufacturing process formed by applying the method of manufacturing a semiconductor device according to the first embodiment to a p anode layer 7a of a body diode (a parasitic diode) 200a of a metal oxide semiconductor field effect transistor (MOSFET) 200. FIG. 5 depicts an argon ion implantation step to be step S3. FIG. 5 depicts the portions to be disposed in the subsequent manufacturing process steps (a front surface electrode 16 to act concurrently as a source electrode and an anode electrode, and a back surface electrode to act concurrently as a drain electrode and a cathode electrode) using dotted lines. As depicted in FIG. 5, the body diode 200a of the MOSFET 200 includes a p anode layer 7a, an n⁻ drift layer 6a, and an n⁺ cathode layer 5b.

The p anode layer 7a is a p well layer (a p base layer) 15 of the MOSFET and the n⁺ cathode layer 5b is an n⁺ drain layer 20 of the MOSFET. A semiconductor base substrate is first prepared that has the n⁻ drift layer 6a epitaxially grown on the front surface of an n⁺ semiconductor substrate to be the n⁺ drain layer 20. A semiconductor substrate may be prepared that has the n⁺ drain layer 20 disposed using the diffusion method on the overall back surface of a bulk-cutout substrate to be the n⁻ drift layer 6a. The p well layer 15, an n⁺ source layer 19, a gate insulating film, a polysilicon gate electrode 17, and an interlayer insulating film 18 of the MOSFET are disposed on the front surface side of the base substrate of the n⁺ drift layer 6a by general methods. A contact hole is formed that penetrates the interlayer insulating film 18 in the depth direction to expose the p well layer 15 and the n⁺ source layer 19 in the contact hole. The ion implantation 8a of the argon 8 is executed before disposing the front surface electrode 16 to be the source electrode using the polysilicon gate electrode 17 and the interlayer insulating film 18 as masks. The range Rp of the argon 8 is set to be shallower than the diffusion depth Xj of the p anode layer 7a similarly in the first embodiment. The conditions of the ion implantation 8a of the argon 8 are same as those of the argon ion implantation process (step S3) of the first embodiment. The platinum paste application process (step S4), the platinum diffusion process (step S5) and the electrode formation process (step S6) are sequentially executed similarly to the first embodiment and the MOSFET 200 is thereby completed.

Setting the platinum concentration of the p anode layer 7a of the body diode 200a of the MOSFET 200 to be high enables reduction of the reverse recovery current IRR of the body diode 200a, reduction of the reverse recovery time trr, and reduction of the forward voltage drop VF. The concentration of the carriers accumulated in the p well layer 15 of the MOSFET 200 (the p anode layer 7a of the body diode 200a) is reduced. An effect is thereby achieved in that the operation of the parasitic npn transistor 200b formed by the n⁺ source layer 19, the p well layer 15, and the n⁻ drift layer 6a is suppressed.

As described, according to the second embodiment, effects identical to those of the first embodiment can be achieved when the present invention is applied to the MOSFET.

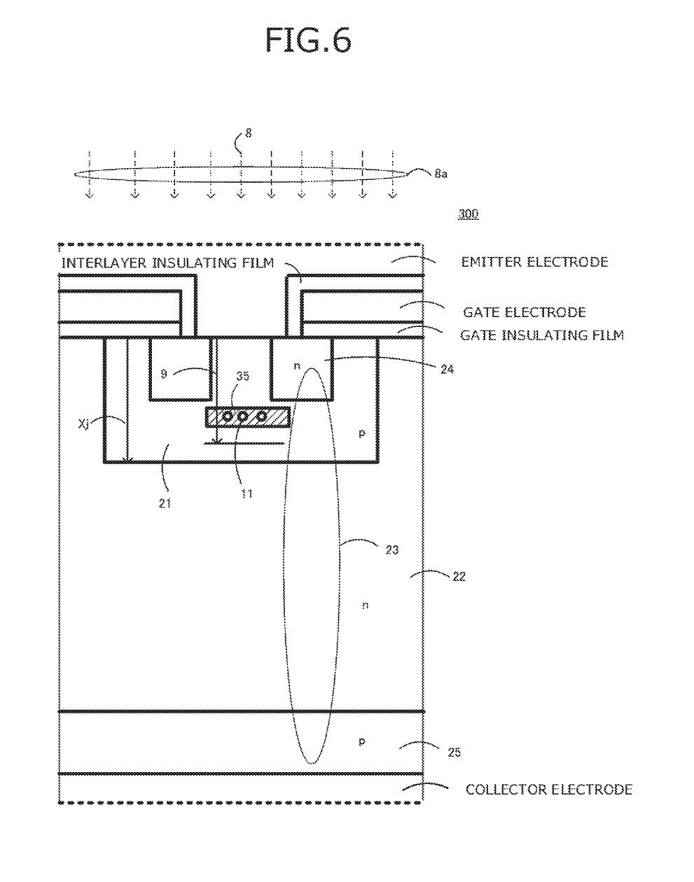

A method of manufacturing a semiconductor device according to a third embodiment will be described. FIG. 6 is a cross-sectional diagram of the semiconductor device manufactured using the method of manufacturing a semiconductor device according to the third embodiment of the present invention. The method of manufacturing a semiconductor device according to the third embodiment is a manufacturing process in which the method of manufacturing a semiconductor device according to the first embodiment is applied to a p base layer 21 of an insulated gate bipolar transistor (IGBT) 300. FIG. 6 depicts an argon ion implantation step (step S3). FIG. 6 also depicts the portions to be disposed in the subsequent manufacturing process steps (a front surface electrode to be an emitter electrode, and a back surface electrode to be a collector electrode) using dotted lines. An n emitter layer 24 is disposed instead of the n⁺ source layer and a p collector layer 25 is disposed instead of the n⁺ drain layer in the method of manufacturing a semiconductor device according to the second embodiment, as the method of manufacturing a semiconductor device according to the third embodiment.

In the third embodiment, similarly to the first embodiment, the range Rp of the argon 8 is set to be shallower than the diffusion depth Xj of the p base layer 21 to be the p semiconductor layer on the front surface side of the base substrate. Localizing the platinum atoms 11 in the p base layer 21 enables reduction of excessive carriers accumulated in the p base layer 21 and suppresses injection of carriers into the n drift layer 22 to thereby enable reduction of the turn-off time. The ON voltage (that corresponds to the forward voltage drop of the diode) can be reduced because the platinum concentration in the n drift layer 22 is reduced. Furthermore, increasing the platinum concentration of the p base layer 21 suppresses injection of the carriers into the n drift layer 22 and can suppress operation of a parasitic npnp thyristor 23. The parasitic npnp thyristor 23 includes the n emitter layer 24, the p base layer 21, the n drift layer 22, and the p collector layer 25.

As described, according to the third embodiment, effects identical to those of the first and the second embodiments can be achieved even when the present invention is applied to the IGBT.

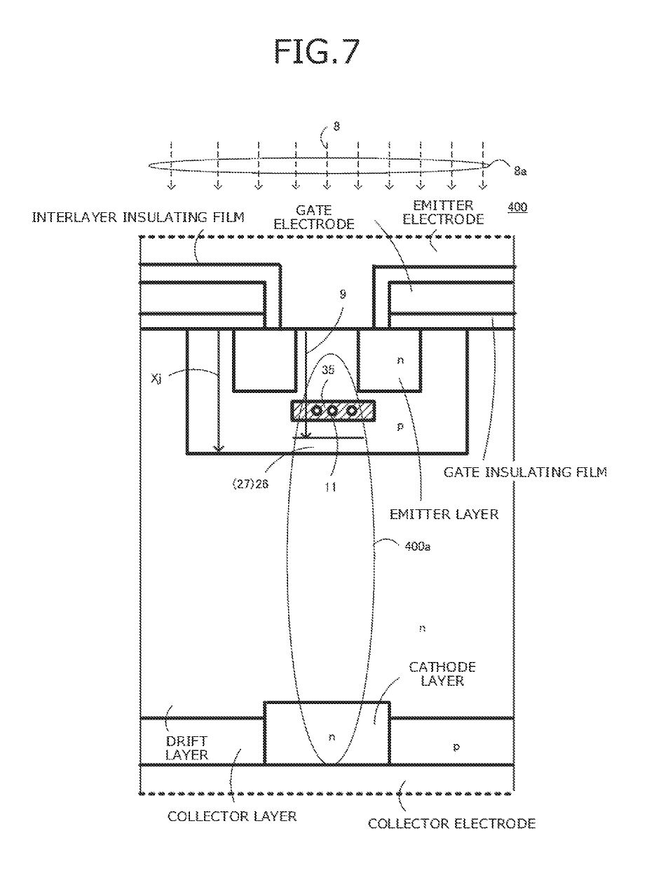

A method of manufacturing a semiconductor device according to a fourth embodiment will be described. FIG. 7 is a cross-sectional diagram of the semiconductor device manufactured using the method of manufacturing a semiconductor device according to the fourth embodiment of the present invention. The method of manufacturing a semiconductor device according to the fourth embodiment is a manufacturing process in which the method of manufacturing a semiconductor device according to the first embodiment is applied to a p anode layer 26 of a diode portion 400a of a reverse-conducting IGBT 400, which is a reverse-conducting type IGBT (Reverse-Conducting IGBT). The p anode layer 26 also acts as a p base layer 27. FIG. 7 depicts an argon ion implantation step (step S3). FIG. 7 also depicts the portions to be disposed in the subsequent manufacturing process steps (a front surface electrode to also act as an emitter electrode and an anode electrode, and a back surface electrode to also act as a collector electrode and a cathode electrode) using dotted lines. A step of disposing an n-type cathode layer on the back surface side of the base substrate only has to be added to the method of manufacturing a semiconductor device according to the third embodiment, as the method of manufacturing a semiconductor device according to the fourth embodiment. For example, the n-type cathode layer is disposed by inverting the conductivity type of the portion corresponding to a diode portion 400a of the p collector layer disposed on the overall face of the back surface of the base substrate, into the n type using ion implantation of an n-type impurity.

In the fourth embodiment, similarly to the first embodiment, the range Rp of the argon 8 is also set to be shallower than Xj of the p anode layer 26. Similarly to the first embodiment, setting the platinum concentration of the p anode layer 26 of the diode portion 400a enables reduction of the reverse recovery current IRR of the diode portion 400a, reduction of the reverse recovery time trr, and reduction of the forward voltage drop VF. Although not depicted, the p anode layer 26 of the diode portion 400a may be independently disposed away from the p base layer 27 of the IGBT. In this case, the ion implantation 8a of the argon 8 may be executed for only the p anode layer 26 or may be executed including the p base layer 27 of the IGBT.

As described, according to the fourth embodiment, effects identical to those of the first to the third embodiments can be achieved even when the present invention is applied to the reverse-conducting IGBT.

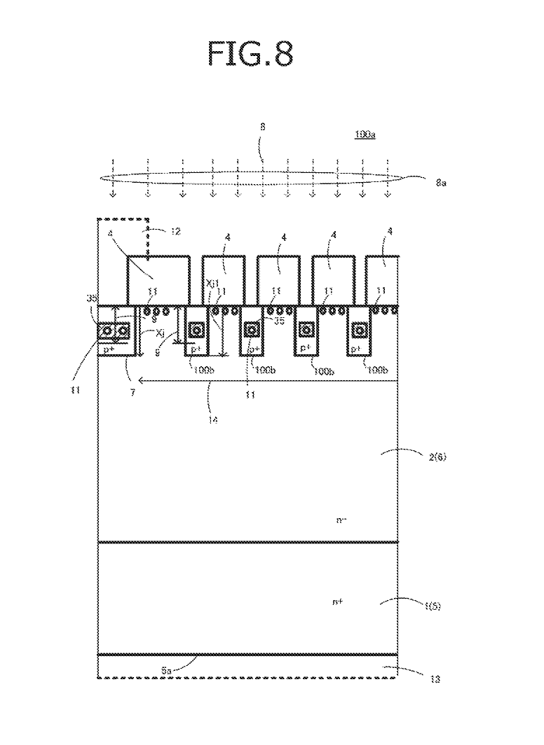

A method of manufacturing a semiconductor device according to a fifth embodiment will be described. FIG. 8 is a cross-sectional diagram of the semiconductor device manufactured using the method of manufacturing a semiconductor device according to the fifth embodiment of the present invention. The method of manufacturing a semiconductor device according to the fifth embodiment is a manufacturing process in which the method of manufacturing a semiconductor device according to the first embodiment is applied to a p guard ring 100b constituting a voltage breakdown structure 14 of the p-i-n diode 100a (see FIG. 2). FIG. 8 depicts an argon ion implantation step (step S3). FIG. 8 depicts the portions to be disposed in the subsequent manufacturing process steps (the front surface electrode 12 to be anode electrode, and the back surface electrode 13 to be a cathode electrode) using dotted lines. The p guard ring 100b constituting the voltage breakdown structure 14 is disposed using ion implantation of a p-type impurity into an edge termination region surrounding the periphery of the active region and the defective layer 9 is disposed inside the p guard ring 100b using ion implantation of argon in the method of manufacturing a semiconductor device according to the first embodiment, as the method of manufacturing a semiconductor device according to the fifth embodiment. For example, the plural p guard rings 100b are disposed concentrically surrounding the periphery of the n⁺ cathode layer 5.

In the fifth embodiment, similarly to the first embodiment, the range Rp of the argon 8 is set to be shallower than the diffusion depth Xj1 of the p guard ring 100b to be the p semiconductor layer on the front surface side of the base substrate. The diffusion depth Xj1 of the p guard ring 100b is often set to be generally deeper than the diffusion depth Xj of the P⁺ anode layer 7. The range of the argon 8 is, therefore, set corresponding to the diffusion depth Xj1 of the p guard ring 100b. The conditions of the ion implantation 8a of the argon 8 into the p guard ring 100b are same as those of the argon ion implantation process (step S3) of the first embodiment except that the range of the argon 8 is set corresponding to the diffusion depth Xj1 of the p guard ring 100b. The method of disposing the platinum localization region 35 into the p guard ring 100b is same as that of the platinum application process (step S4) and the platinum diffusion process (step S5) of the first embodiment.

Although the example of the p-i-n diode 100a depicted in FIG. 2 is taken as the element to be disposed in the active region, the element is not limited hereto and the present invention is also applicable to a guard ring constituting the voltage breakdown structure of each of various types of semiconductor element described in the second to the fourth embodiments. The platinum concentration of the n⁻ drift layer 6 beneath the p guard ring 100b (on the cathode side of the p guard ring 100b) can be reduced by ion-implanting 8a the argon 8 into the p guard ring 100b and diffusing the platinum atoms 11 from the surface of the n⁺ cathode layer 5 (the back surface of the n⁺ semiconductor substrate 1). As a result, the concentration of the recombination centers formed by the platinum atoms 11 (the lifetime killer concentration) in the n⁻ drift layer 6 beneath the p guard ring 100b is reduced, and the leak current Iro in the voltage breakdown structure 14 can be reduced. The ion implantation 8a of the argon 8 may executed for a point at which the depletion layer of the p guard ring 100b does not spread. The platinum atoms 11 may be diffused in the surface layer on the front surface side of the base substrate of the p guard ring 100b at the platinum paste application step and the platinum diffusion step, without executing the ion implantation 8a of the argon 8 thereinto by disposing a mask on the p guard ring 100b.

As described, according to the fifth embodiment, the voltage breakdown structure having the platinum concentration distribution same as that of each of the first to the fourth embodiments can be formed. The leak current in the voltage breakdown structure can thereby be reduced.

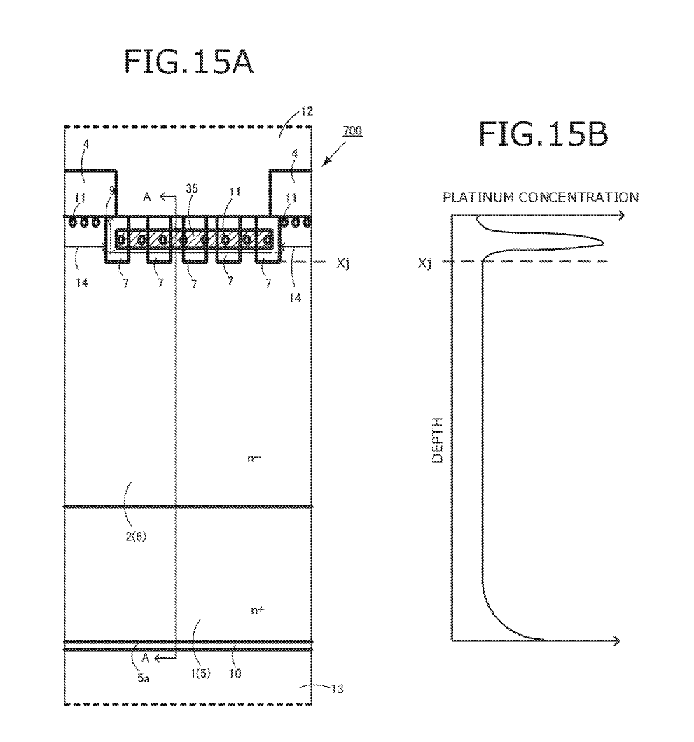

A method of manufacturing a semiconductor device according to a sixth embodiment will be described. FIG. 15A is a cross-sectional diagram of the semiconductor device manufactured using the method of manufacturing a semiconductor device according to the sixth embodiment of the present invention. The semiconductor device manufactured using the method of manufacturing a semiconductor device according to the sixth embodiment is a merged PiN/Schottky (MPS) diode (an MPS diode) 700. FIG. 15A is a cross-sectional diagram of the MPS diode 700 and FIG. 15B is a distribution diagram of the platinum concentration along cut line A-A of FIG. 15A. The semiconductor device manufactured using the method of manufacturing a semiconductor device according to the sixth embodiment differs from the semiconductor device manufactured using the method of manufacturing a semiconductor device according to the first embodiment in that the p⁺ anode layer 7 is selectively disposed on the front surface side of the base substrate to expose the n⁻ drift layer 6 in the surface, and the exposed n⁻ drift layer 6 and the front surface electrode 12 contact each other by a Schottky contact.

For example, when Conventional Example (see FIGS. 10 and 12) is applied to the MPS diode, because the platinum atoms are segregated in the uppermost surface of the front surface of the base substrate according to the platinum concentration distribution of Conventional Example, defects may be generated in the Schottky contact surface due to the platinum atoms segregated in the uppermost surface of the base substrate, and may cause the occurrence of leak current. In contrast, in the MPS diode 700 according to the sixth embodiment of the present invention, the depth as the position of the maximal concentration of the platinum atoms 11 can be moved to a position near the range of argon that is deeper than the uppermost surface of the front surface of the semiconductor base substrate using the argon ion implantation step (step S3). The platinum concentration in the Schottky contact surface is thereby reduced compared to a case where Conventional Example is applied to the MPS diode, and defects can be suppressed that are generated by the localization of the platinum atoms 11 in the surface layer of the front surface of the base substrate to enable the occurrence of leak current to be suppressed. Yield can therefore be improved.

As described, according to the sixth embodiment, the MPS diode can be manufactured that has a platinum concentration distribution identical to those of the first to the fourth embodiments. Leak current of the MPS diode can thereby be reduced.

The present invention can be changed variously in the description above without departing from the spirit of the invention and, in the embodiments, for example, the dimensions, the impurity concentrations, and the like of the components are set corresponding to the required specifications and the like.

According to the semiconductor device and the method of manufacturing a semiconductor device, of the present invention, platinum atoms to be the lifetime killer can be localized in the second semiconductor layer to be the anode layer, the base layer, and the guard ring layer, and an effect is therefore achieved in that the reverse recovery current can be reduced, the reverse recovery time can be shortened, and the forward direction voltage drop can be reduced.

As described, the semiconductor device and the method of manufacturing a semiconductor device according to the present invention are useful for semiconductor devices that include a p semiconductor layer in the surface layer of the front surface of the base substrate thereof such as an anode layer of a diode, a p base layer of a MOSFET or an IGBT, and a guard ring of an edge termination region.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a first semiconductor layer of a first conductivity type;
a second semiconductor layer of a second conductivity type and disposed in the first semiconductor layer, the second semiconductor layer having an impurity concentration that is higher than that of the first semiconductor layer; and
an argon-introduced region in the second semiconductor layer, including argon and disposed at a predetermined depth in the second semiconductor layer from a pn junction between the first semiconductor layer and the second semiconductor layer,
wherein the semiconductor device includes platinum diffused in the first semiconductor layer and the second semiconductor layer, and
the platinum has a platinum concentration distribution that has a maximal concentration in the argon-introduced region.

2. The semiconductor device according to claim 1, wherein the predetermined depth is a position at which a value obtained by integrating an impurity concentration of the second semiconductor layer from the pn junction toward the first surface is a critical integral concentration of the second semiconductor layer.

3. The semiconductor device according to claim 1, wherein a length from the pn junction toward the first surface side to the predetermined depth is a diffusion length of a first conductivity type carrier in the second semiconductor layer.

4. A method of manufacturing a semiconductor device, comprising:
selectively forming a second semiconductor layer of a second conductivity type and having an impurity concentration that is higher than that of a first semiconductor layer of a first conductivity type, in a surface layer of a first surface of the first semiconductor layer;
forming an argon-introduced region that includes argon, at a predetermined depth from a pn junction between the first semiconductor layer and the second semiconductor layer, by ion implanting argon from the first surface, such that the argon-introduced region has a thickness lass than that of the second semiconductor layer; and
diffusing platinum into the second semiconductor layer from a second surface of the first semiconductor layer so as to localize the platinum in the argon introduced region.

5. The method of manufacturing a semiconductor device, according to claim 4, wherein diffusing the platinum into the second semiconductor layer from the first semiconductor layer comprises:
applying a platinum paste to the second surface of the first semiconductor layer; and
heat-treating the platinum paste to diffuse the platinum into the second semiconductor layer.

6. The method of manufacturing a semiconductor device, according to claim 5, wherein the platinum paste is heat-treated at a temperature ranging from between 800 to 1,000 degrees C.

7. The method of manufacturing a semiconductor device, according to claim 4, wherein the argon-introduced region is formed at a depth that is one half of a depth of the second semiconductor layer from the first surface to a the pn junction.

8. The method of manufacturing a semiconductor device, according to claim 4, wherein forming the argon-introduced region includes adjusting a location of the argon-introduced region by adjusting an acceleration energy of the ion implanting of the argon.

9. The method of manufacturing a semiconductor device, according to claim 8, wherein the second semiconductor layer is disposed at a depth ranging from 1 to 10 μm from the first surface, and
the acceleration energy of the ion implanting of the argon ranges from 0.5 to 30 MeV.

10. The method of manufacturing a semiconductor device, according to claim 8, wherein the acceleration energy of the ion implanting of the argon is adjusted so that the range of the argon is positioned between the pn junction and a position at which a value obtained by integrating an impurity concentration of the second semiconductor layer from the pn junction toward the first surface is a critical integral concentration of the second semiconductor layer.

11. The method of manufacturing a semiconductor device, according to claim 4, wherein selectively forming the second semiconductor layer in the surface layer of the first surface of the first semiconductor layer comprises:
positioning a mask member on the first surface of the first semiconductor layer, the mask member having an opening therein; and
diffusing a second conductivity type impurity onto the mask member to be ion-implanted through the opening of the mask member to form the second semiconductor layer.

12. The method of manufacturing a semiconductor device, according to claim 11, wherein the mask member has a thickness sufficient to block an ion-implantation of the argon.

13. The method of manufacturing a semiconductor device, according to claim 11, wherein the mask member comprises one of a resist film or an insulating film.

14. The method of manufacturing a semiconductor device, according to claim 11, wherein boron is ion-implanted as the second conductivity type impurity.

15. The method of manufacturing a semiconductor device, according to claim 4, wherein the second semiconductor layer is disposed as a guard ring layer constituting a voltage breakdown structure in a terminal region surrounding a periphery of one of an anode layer of a pn junction diode, an anode layer of a body diode of an insulated gate field effect transistor, a base layer of an insulated gate bipolar transistor, an anode layer of a diode portion of a reverse-conducting insulated gate bipolar transistor, and an active region.

16. The semiconductor device according to claim 1, wherein the second semiconductor layer is a p base layer of a metal oxide semiconductor field effect transistor (MOSFET).

17. The semiconductor device according to claim 1, wherein the semiconductor device is one of a metal oxide semiconductor field effect transistor (MOSFET), an insulated gate bipolar transistor (IGBT), and a reverse-conducting insulated gate bipolar transistor (RC-IGBT).

18. The semiconductor device according to claim 1, wherein the second semiconductor layer is a p guard ring.

19. The semiconductor device according to claim 1, wherein the second semiconductor layer comprises a Schottky contact surface in which the first semiconductor layer forms a Schottky contact with a front surface electrode, and
a platinum concentration of the Schottky contact surface is lower than that of the argon introduced region.

20. The method of manufacturing a semiconductor device, according to claim 4, wherein the platinum is localized to have a platinum concentration distribution that has a maximal concentration in the argon introduced region.
